(19) United States
(12) Patent Application Publication
(10) Pub. No.: US 2021/0191482 A1
(43) Pub. Date: Jun. 24, 2021

(54) DISPLAY PANEL, CHIP-ON-FILM, AND DISPLAY DEVICE

(71) Applicants: CHENGDU BOE OPTOELECTRONICS TECHNOLOGY CO., LTD., Chengdu, Sichuan (CN); BOE TECHNOLOGY GROUP CO., LTD., Beijing (CN)

(72) Inventor: Hongjun ZHOU, Beijing (CN)

(73) Assignees: CHENGDU BOE OPTOELECTRONICS TECHNOLOGY CO., LTD., Chengdu, Sichuan (CN); BOE TECHNOLOGY GROUP CO., LTD., Beijing (CN)

(21) Appl. No.: 17/271,224

(22) PCT Filed: Jun. 3, 2020
(86) PCT No.: PCT/CN2020/094159

§ 371 Date: Feb. 25, 2021

(30) Foreign Application Priority Data
Jun. 5, 2019 (CN) 201910487524.0

(51) Int. Cl. G06F 1/18

(52) U.S. Cl. CPC G06F 1/189; G06F 1/1652

(57) ABSTRACT

Provided are a display panel, chip-on-film, and display device. The display panel includes a display region and a bonding region; bonding region includes: a first substrate, and at least one row of first pins arranged on one side of the first substrate, the first pins being arranged along the first direction and being independent of each other; the distance between two adjacent first pins in the same row at the end near the display region is greater than the distance (d2) at the other end away from the display region, such that the whole of the at least one row of first pins has an inverted trapezoid-like structure having long sides near the display region.

### CROSS REFERENCE TO RELATED APPLICATIONS

This application claims priority to Chinese patent application No. 201910487524.0 filed on Jun. 5, 2019, and entitled “A DISPLAY PANEL, CHIP-ON-FILM FILM, AND DISPLAY DEVICE”, the entire disclosure of which is incorporated herein by reference for all purposes.

### TECHNICAL FIELD

Embodiments of the present disclosure relate to a display panel, a chip-on-film film, and a display device.

### BACKGROUND

With the increasing popularity of flexible display products, flexible display products are developing towards higher resolution and ultra-narrow bezel. In order to narrow the drive side bezel of the flexible display device, in the current preparation process, the drive chips are generally bonded in two ways, namely Chip On Film (COF, as shown in FIG. 1) and Chip On Plastic (COP). Compared with a COP bonding way, the pins in a COF bonding way have smaller bonding spacing, and there is no need to design regions, such as internal pin bonding (ILB), and flexible board (FPC) on the backplane, which can save the lower frame of the display device on the backplane, increase the number of typesetting, and improve the utilization rate of the backplane glass. In addition, the integrated circuit (IC) and FPC bonding process are not needed, thus the amount of processes are decreased and the loss of process yield is reduced.

### SUMMARY

Embodiments of the present application provides a display panel, Chip-on-film film and a display device, which can improve the space utilization rate of the display panel.

An embodiment of the present application provides a display panel. The display panel comprises a display region and a bonding region. The bonding region comprises a first substrate and at least one row of first pins provided on a side of the first substrate, the first pins are provided along a first direction and are independent of each other, and a distance between two adjacent first pins in a same row at one end near the display region is larger than a distance between the two adjacent first pins in the same row at the other end away from the display region, so that the at least one row of the first pins as a whole exhibit an inverted trapezoidal structure with a long side near the display region.

For example, the first pins in the same row are symmetrically distributed relative to a first reference line, and the first reference line is the perpendicular bisector of a boundary of the bonding region along the first direction.

For example, an included angle between each of the first pins and the first reference line gradually increases with increase of a distance between each of the first pins and the first reference line.

For example, the included angle between each of the first pins and the first reference line is greater than or equal to about 78 degrees, and less than or equal to 84 degrees.

For example, each of the first pins has same shape and size.

For example, each of the first pins has a width greater than or equal to about 11 μm, and less than or equal to about 47 μm; and each of first pins has a length greater than or equal to about 600 μm, and less than or equal to about 1100 μm.

For example, a spacing between various of the first pins is greater than or equal to about 3 μm, and less than or equal to about 10 μm.

At least one embodiment of the present application also provides a chip-on-film film. The chip-on-film film can be applied to the display panel, the chip-on-film film is attached to the bonding region of the display panel, and the chip-on-film film comprises a second substrate and at least one row of second pins arranged on a side of the second substrate. The second pins are arranged along a second direction and are independent of each other, and each of the second pins is configured to be bonded with a corresponding first pin, a distance between two adjacent second pins in a same row at one end near the display region is greater than a distance between the two adjacent second pins in the same row at the other end away from the display region.

For example, the second pins in the same row are symmetrically distributed relative to a second reference line, and the second reference line is a perpendicular bisector of a boundary of the chip-on-film film along the first direction.

For example, an included angle between each of the second pins and the second reference line gradually increases with increase of a distance between each of the second pins and the second reference line.

For example, the included angle between each of the second pins and the second reference line is greater than or equal to about 78 degrees, and less than or equal to 84 degrees.

For example, each of the second pins has same shape and size.

For example, each of the second pins has a width greater than or equal to about 6 μm, and less than or equal to about 43 μm; and each of second pins has a length greater than or equal to about 800 μm, and less than or equal to about 1300 μm.

For example, a spacing of various of the second pins is greater than or equal to about 7 μm, and less than or equal to about 15 μm.

At least one embodiment of the present application also provides a display device, comprising the display panel and/or the chip-on-film film.

### BRIEF DESCRIPTION OF THE DRAWINGS

Embodiments of the present disclosure will be described in more detail below with reference to accompanying drawings to allow an ordinary skill in the art to more clearly understand embodiments of the present disclosure, in which:

FIG. 1 shows a schematic diagram of a COF bonding mode;

FIG. 2 shows a schematically plane structural diagram of a bonding region of a display panel;

FIG. 3 shows a schematically plane structural diagram of a display panel;

FIG. 4 shows a schematically plane structural diagram of a bonding region of a display panel provided by an embodiment of the present application;

FIG. 5 shows a schematically plane structural diagram of a display panel provided by an embodiment of the present application;

FIG. 6 shows a schematic diagram of a geometric model for shortening the height of a fanout region of a display panel provided by an embodiment of the present application;

FIG. 7 shows a layout diagram of a bonding region and a fanout region;

FIG. 8 shows a layout diagram of a bonding region and a fanout region provided by an embodiment of the present application;

FIG. 9 shows a schematically structural diagram of a lower frame of a display panel without pad bending provided by an embodiment of the present application;

FIG. 10 shows a schematic structural diagram of a lower frame of a display panel with pad bending provided by an embodiment of the present application;

FIG. 11 shows a schematically structural diagram of a lower frame after a display panel with pad bending is bent provided by an embodiment of the present application; and

FIG. 12 shows a schematically plane structural diagram of a chip-on-film film provided by an embodiment of the present application.

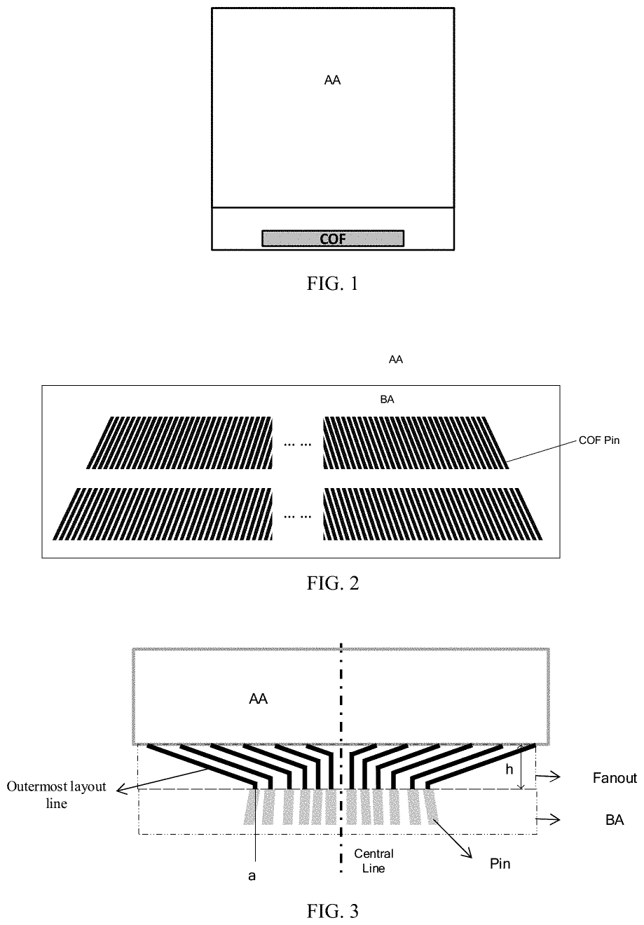

### DETAILED DESCRIPTION

The technical solutions of the embodiments will be described in a clearly and fully understandable way in connection with the drawings related to the embodiments of the present disclosure. Apparently, the described embodiments are just a part but not all of the embodiments of the present disclosure. Based on the described embodiments herein, one of ordinary skill in the art can obtain other embodiment(s), without any inventive work, which should be within the scope of the present disclosure.

Unless otherwise defined, all the technical and scientific terms used herein have the same meanings as commonly understood by one of ordinary skill in the art to which the present disclosure belongs. The terms, such as “first,” “second,” or the like, which are used in the present application, are not intended to indicate any sequence, amount or importance, but for distinguishing various components. Also, the terms, such as “comprise/comprising,” “include/including,” or the like are intended to specify that the elements or the objects stated before these terms encompass the elements or the objects and equivalents thereof listed after these terms, but not preclude other elements or objects. The terms, “on,” “under,” or the like are only used to indicate relative position relationship, and when the absolute position of the object which is described is changed, the relative position relationship may be changed accordingly.

In order to make the above objects, elements, and advantages of this application more obvious and understandable, the embodiments of this application will be further described in detail with reference to the drawings and exemplary embodiments.

The inventor found that, in the related chip-on-film (COF) bonding mode, the height of a fanout lead region connecting a COF bonding region and an effective display region is large, which results in the waste of the lower frame space of the display substrate.

In the related art, the reason for the higher height of fanout lead region is related to the lead structure of bonding region. As shown in FIG. 2, in order to compensate the thermal deformation of flexible substrate, chip-on-film pins in the COF Bonding mode of the flexible OLED product is designed to be inclined, and the whole structure is a regular trapezoidal structure with a short side near the display region. As shown in FIG. 3, in this structure, the connection position between the outermost COF pin and the Fanout layout (that is, the outlet point a of the outermost layout line) is near the middle portion of COF, and if a process y-direction compensation is considered, lengths of pins will be lengthened along a COF pin inclination angle, so that the outlet point a of outermost layout line is closer to the middle portion of COF, resulting in a longer inclination line of the outermost layout line in the Fanout region, which in turn leads to the increase of the height of fanout region.

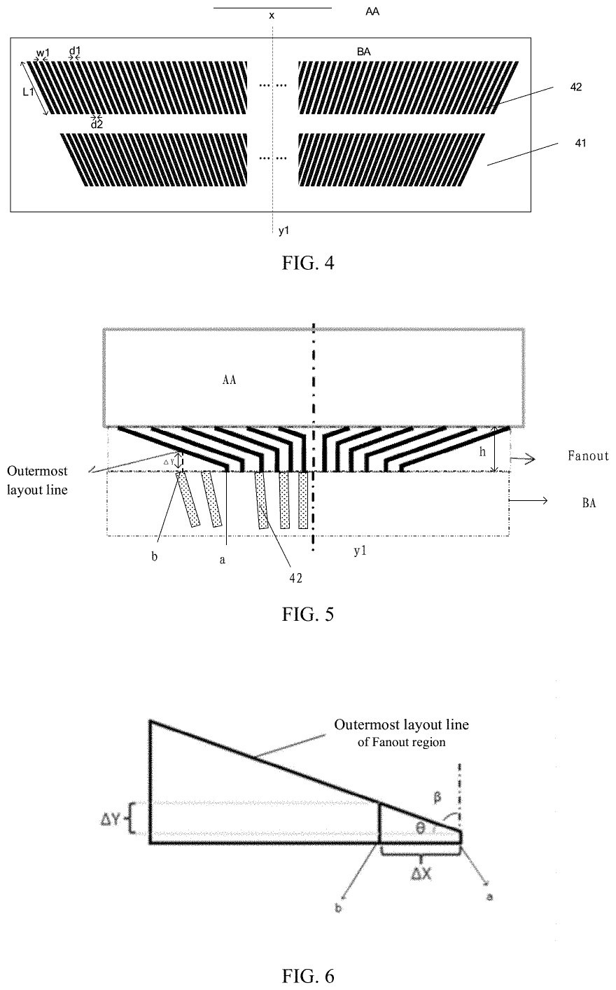

An embodiment of the present application provides a display panel. As shown in FIG. 4, the display panel includes a display region AA and a bonding region BA. The bonding region BA includes a first substrate 41 and at least one row of first pins 42 arranged on a side of the first substrate 41. The first pins 42 are arranged along a first direction x, such as the horizontal direction from left to right on the paper surface, and the first pins 42 are independent of each other. The distance d1 between the two adjacent first pins 42 in the same row at the end near the display area AA is greater than the distance d2 at the other end away from the display area AA, so that the at least one row of first pins exhibit an inverted trapezoid structure having a long side near the display area.

As shown in FIG. 5, the Fanout region includes a plurality of layout lines connecting data signal lines of the display region AA and the first pins 42 of the bonding region BA. The height h of the Fanout region affects the size of the lower frame, and the decisive factor limiting the height h of the fanout region is the outermost layout line. The fanout region needs to enable the outermost layout line to have a space for the arrangement of lines. As shown in FIG. 5, the outermost layout line in the fan-out region include an inclination section and a vertical section, and the layout line in the vertical section can be shortened. That is, the higher the height of the outermost layout line in the fanout region, the more compressible space there is.

In the present embodiment, the outlet line point b of the outermost layout line in the fanout region moves to an edge of the bonding region BA relative to an outlet line point a in a relevant design. Assuming that an inclination angle of the inclined section of the outermost layout line in the fanout region is unchanged (the same as the relevant design), the height of the layout line in the vertical section can be increased by ΔY compared with the relevant design. That is to say, if the layout line in the vertical section is not included, the height of the fanout region in the present embodiment can be shortened by ΔY, and the geometric model is shown in FIG. 6. In FIG. 6, theta (θ) is an inclination angle of the inclined section of the outermost layout line, ΔX is a distance between the outlet line point a and the outlet line point b, and the height of the layout line in the vertical section can be increased by ΔY=ΔX*tan θ. If the process Y-direction compensation is considered, after the first pin 42 is elongated along the inclination angle, the outlet line point b of the outermost layout line is closer to the side of the bonding region BA, and the value of ΔX may be larger, and the decreaseable height ΔY of the Fanout region is also larger, so that the bezel can be narrower.

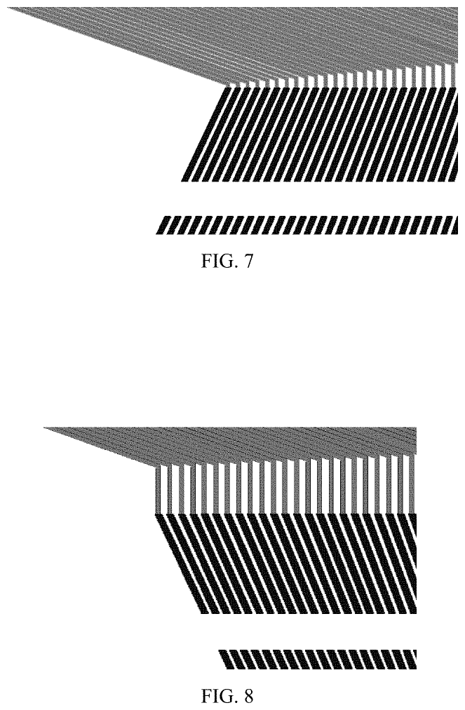

Because the decreaseable height ΔY of the Fanout region is related to the distance ΔX and the inclination angle θ, in the case where the amount of rows of the first pins 42 is greater, the length is longer, and the inclination angle θ is larger, the decreaseable dimension ΔY is larger. In the case where the overall height h of the Fanout is kept unchanged, FIG. 7 shows a layout diagram of a bonding region and a fanout region, and FIG. 8 shows a layout diagram of a bonding region and a fanout region provided by an embodiment of the present application. The length of the layout line in the vertical section of the whole Fanout region of the display panel provided by the embodiment of the application is longer, and a narrower lower frame can be obtained by increasing the length ΔY of the layout line in the vertical section. Or, for example, under the condition of the same frame width, more design space can be reserved for other circuit units by shortening the length of the layout line in the vertical section, so that the product stability and reliability can be improved.

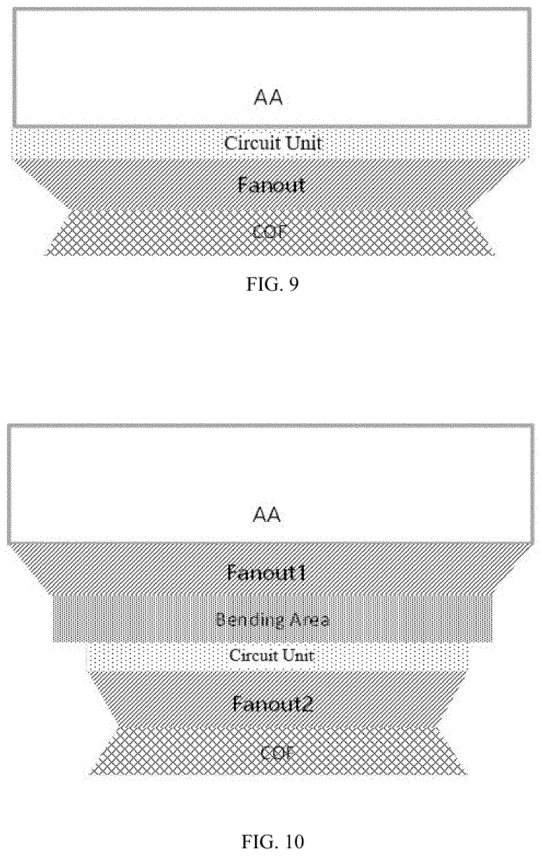

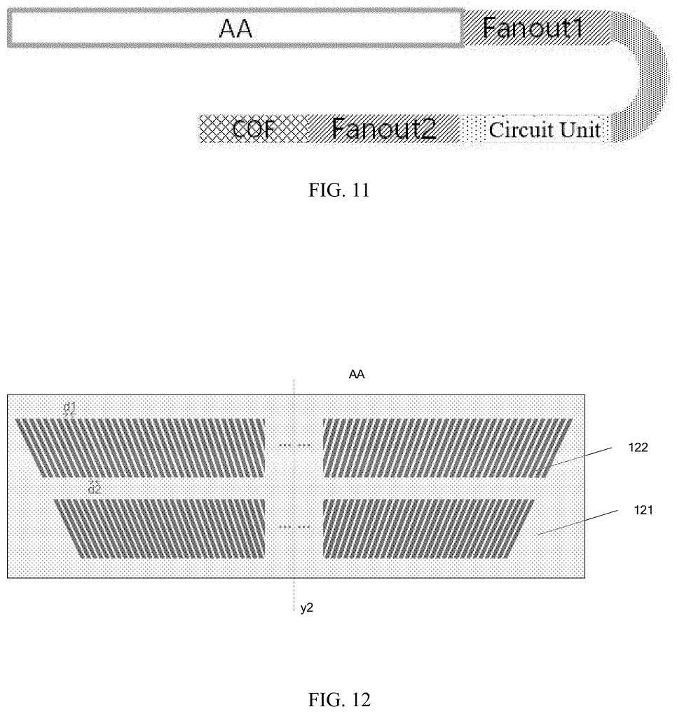

For a display panel with no Pad Bending Area in the bonding region (as shown in FIG. 9), the decreaseable region in height is the Fanout region, and the overall height of the fanout region is directly related to the lower frame of the display device. If the height of layout lines of the fanout region can be reduced, the lower frame of the final product can be narrowed. For the display panel with a Pad Bending Area in the bonding region, as shown in FIG. 10, the decreaseable region in height is a second Fanout2 region, and the height of the second Fanout region will not affect the width of the lower frame of the final product (the width of the lower frame is related to the distance between the bending area and the product display region), but the height of fanout2 region will affect the length of the part bent to the back of the display device after the display device is bent, as shown in FIG. 11, if the fanout2 region is too long, the fanout2 region may interfere with other functional modules of the display device. By shortening the length of the structure bent to the back of the display device, more space can be reserved for other functional modules and better results can be achieved. The positions of circuit units and fanout regions in FIG. 9 can be exchanged, and here it is just an example. The positions of circuit units and the second Fanout2 region in FIG. 10 can be exchanged, and here it is just an example.

The technical scheme provided by the present embodiment, the distance between two adjacent first pins in the same row of the bonding region at one end near the display region is larger than the distance between two the adjacent first pins in the same row of the bonding region at the other end away from the display region, so that at least one row of the first pins have an inverted trapezoidal structure with a long side near the display region as a whole, so that the outermost layout line of the Fanout region connecting the bonding region and the display region can approach the edge of the display panel. Compared with the positive trapezoidal structure having pins in the bonding region with the short side near the display region as a whole, the length of the layout lines in the vertical section of layout lines of the Fanout region in the present application is longer, and a narrower lower frame can be realized by increasing the height of the layout lines in the vertical section, or more design space can be reserved for other circuit units by shortening the height of the layout lines in the vertical section under the condition of the same frame, so that the space utilization rate of the display substrate can be improved. In addition, by narrowing the lower frame of the display panel, the typesetting quantity of the display panel on backboard can be increased, the typesetting utilization rate of the backboard glass can be improved, and better economic benefits can be realized. The structural design of the first pins in the bonding region BA in the present embodiment of the application has a good compensation effect for the misalignment caused by the thermal deformation in a flexible substrate process, the temperature and stress deformation in a bonding process, and the alignment tolerance of equipment and other factors.

For example, the first pins 42 in the same row may be symmetrically distributed with respect to a first reference line y1, and the first reference line y1 is the perpendicular bisector of the boundary of the bonding region BA along the first direction, as shown in FIG. 4 or FIG. 5.

Considering the effect of thermal deformation in different regions in the bonding process, the first pins 42 in the same row are designed with a gradually changed period (Pitch), that is, the middle period is small, and periods on the two sides are large, and the first pins 42 are arranged from the first reference line y1 in the middle to the two sides in such a way that the periods gradually increase. The period of the first pins 42 in the same row decreases at the end away from the display region and increases at the other end near the display region, as shown in FIG. 4 or FIG. 5.

In an example, the period range of the first pins 42 may be between 21 μm and 50 μm, and the gradually changed period range of the first pins 42 in the same display panel may be, for example, 34 μm˜30 μm˜34 μm.

The included angle θ between each of the first pins 42 and the first reference line y1 may gradually increase as the distance between each of the first pins 42 and the first reference line y1 increases. The included angle β between each of the first pins 42 and the first reference line y1 may be, for example, greater than or equal to about 78 degrees and less than or equal to about 84 degrees. The maximum inclination angle of the first pins 42 (that is, the inclination angle θ of the outermost first pin) ranges from 6 degrees to 12 degrees. For example, the maximum inclination angle can be about 8 degrees, that is, the included angle θ between an extending direction of the first pins 42 and the first direction ranges from 6 to 12 degrees. The inclination angle θ and the included angle θ between the first pins 42 and the first reference line y1 are complementary angles to each other, that is, the two angles add up to about 90 degrees.

In order to obtain the same bonding area between each of the first pins 42, each of the first pins 42 have the same shape and size, that is, the width and length of each of the first pins 42 are the same. For example, the width w1 of each of the first pins 42 may be greater than or equal to about 11 μm and less than or equal to about 47 The length L1 of each of the first pins 42 in the same row may be greater than or equal to about 600 μm and less than or equal to about 1100 μm.

Because the middle period of the first pins 42 is small and the periods on the two sides are large, the distance d between two adjacent first pins 42 in the same row gradually increases from the first reference line y1 in the middle to the two sides. Each distance d of the first pins 42 may be greater than or equal to about 3 μm and less than or equal to about 10 μm.

In an example, width, length, spacing, and period of the first pins 42 can be designed according to the situation, and the corresponding values are not limited in the present embodiments.

In common flexible mobile phone products, the distance ΔX between the outlet line points of the bonding region is generally above 200 μm, so that the fanout region has tens of microns or even hundreds of microns of space for being saved, that is, a larger Δy can be designed to narrow the frame. With the development of higher resolution of display devices, the periods of the first Pins 42 will become smaller and smaller in future, and the corresponding width of the first pins 42 will also be reduced. To meet the requirements of the bonding region, the height of pins needs to be correspondingly increased, and the amount of the rows of the first pins 42 also tends to increase, so the distance Δx will be larger, and the frame size that can be reduced in the present design will be more significant, that is, the height ΔY of the vertical section in the fanout region can be made higher, thus making the frame region narrower. In addition, if different devices and different processes increase the demand for the compensation along the inclination direction of the first pins on the backplane, the frame size that can be reduced will also be larger. In this way, the embodiments of the present application can make full use of the reduceable portion in size to achieve a narrow bezel.

In the present application, the arrangement mode of the first pins in the bonding region is optimized, and a narrower lower frame design is realized while maintaining the excellent compensation effect of the inclined design scheme, so that better product effects and economic benefits are realized.

Another embodiment of the present application also provides a chip-on-film film, as shown in FIG. 12, the flip-chip film can be applied to the display panel described in any one of the above embodiments. The chip-on-film can be attached to the bonding region of the display panel. The chip-on-film can include a second substrate 121 and at least one row of second pins 122 arranged on a side of the second substrate 121, where the second pins 122 are arranged along a first direction and are independent of each other, and each of the second pins 122 is configured to be bonded with different first pins 42. The distance between two adjacent second pins 122 in the same row at one end near the display region AA is greater than the distance between the two adjacent second pins 122 in the same row at the other end away from the display region.

The second pins 122 in the same row are symmetrically distributed relative to a second reference line y2, and the second reference line y2 is a perpendicular bisector of a boundary of the chip-on-film film along the first direction

The included angle between each of the second pins 122 and the second reference line y2 gradually increases with increase of a distance between each of the second pins 122 and the second reference line y2.

The included angle between each of the second pins 122 and the second reference line y2 is greater than or equal to about 0 degree and less than or equal to 12 degrees.

Each of the second pins 122 has the same shape and size. Correspondingly, the width of each of the second pins 122 is greater than or equal to about 6 μm and less than or equal to about 43 μm. The length of each of second pins 122 is greater than or equal to about 700 μm and less than or equal to about 1000 μm. The spacing of the second pins 122 is greater than or equal to about 7 μm and less than or equal to about 15 μm.

To match with the first pins 42 on the display panel, the inclination angle of each of the second pins 122 is the same as the corresponding inclination angle θ of each of the first pins, and accordingly, the inclination angle of each of the second pins 122 and the included angle between each of the second pins 122 and the second reference line y2 are complementary angles.

For example, to avoid defects caused by misalignment, the width of the second pins 122 may be narrower than the width of corresponding first pins by 4-5 μm, and the length of the second pins 122 may be longer than the length of corresponding first pins by about 200 μm.

With regard to the chip-on-film in the present embodiment, the structural design of the second pins is matched with the design of the first pins, and the structure can refer to the description in the embodiments of the display panel, and the content is not repeated here.

Another embodiment of the present application also provides a display device, and the display device includes the display panel described in any one of the above embodiments and/or the chip-on-film described in any one of the above embodiments.

The display device in this embodiment can be any product or component with display function, such as electronic paper, mobile phone, tablet computer, television, notebook computer, digital photo frame, navigator, etc.

The embodiments of the present application provides a display panel, a chip-on-film film and a display device. The distance between two adjacent first pins in the same row of the bonding region at one end near the display region is larger than the distance between the two adjacent first pins in the same row of the bonding region at the other end facing away from the display region, and the whole structure is similar to an inverted trapezoid structure with the long side near the display region, so that the outermost layout line of the fanout region connecting the bonding region and the display region can approach the edge of the display panel. Compared with the positive trapezoidal structure having pins in the bonding region with the short side near the display region as a whole, the layout lines of the vertical section in the fanout region is longer. By increasing the height of the layout lines in the vertical section, the vertical height of the inclination layout lines along the first direction can be made smaller, and a narrower lower frame can be realized. Or under the condition of the same frame, more design space can be reserved for other circuit units by shortening the height of the layout lines in the vertical section, so that the space utilization rate of the display substrate can be improved.

The various embodiments in this specification are described in a progressive manner. Each embodiment is described by the differences from other embodiments, and the same or similar parts between the various embodiments are referred to each other

The following statements should be noted:

(1) The accompanying drawings involve only the structure(s) in connection with the embodiment(s) of the present disclosure, and other structure(s) can be referred to common design(s).

(2) Without conflicting with each other, the embodiments of the present disclosure and the elements in the embodiments can be combined with each other to obtain new embodiments, the new embodiments shall also belong to the scope of the present disclosure.

The described above is only the exemplary embodiments of the present disclosure, and the scope of the present disclosure is not limited thereto. A person of ordinary skill in the art can make various changes and modifications without departing from the technical scope of the embodiments of the present disclosure, and such changes and modifications shall fall into the scope of the present disclosure.

1. A display panel, comprising:
a display region and a bonding region, wherein
the bonding region comprises: a first substrate and at least one row of first pins provided on a side of the first substrate, the first pins are provided along a first direction and are independent of each other, and
a distance between two adjacent first pins in a same row at one end near the display region is larger than a distance between the two adjacent first pins in the same row at the other end away from the display region, so that the at least one row of the first pins as a whole exhibit an inverted trapezoidal structure with a long side near the display region.

2. The display panel according to claim 1, wherein the first pins in the same row are symmetrically distributed relative to a first reference line, and the first reference line is the perpendicular bisector of a boundary of the bonding region along the first direction.

3. The display panel according to claim 2, wherein an included angle between each of the first pins and the first reference line gradually increases with increase of a distance between each of the first pins and the first reference line.

4. The display panel according to claim 2, wherein the included angle between each of the first pins and the first reference line is greater than or equal to about 78 degrees and less than or equal to 84 degrees.

5. The display panel according to claim 1, wherein each of the first pins has same shape and size.

6. The display panel according to claim 5, wherein each of the first pins has a width greater than or equal to about 11 μm, and less than or equal to about 47 μm; and
each of first pins has a length greater than or equal to about 600 μm, and less than or equal to about 1100 μm.

7. The display panel according to,
wherein a spacing between various of the first pins is greater than or equal to about 3 μm, and less than or equal to about 10 μm.

8. A chip-on-film film, wherein the chip-on-film film can be applied to the display panel according to claim 1, the chip-on-film film is attached to the bonding region of the display panel, and the chip-on-film film comprises:
a second substrate and at least one row of second pins arranged on a side of the second substrate, wherein the second pins are arranged along a second direction and are independent of each other, and each of the second pins is configured to be bonded with a corresponding first pin,
a distance between two adjacent second pins in a same row at one end near the display region is greater than a distance between the two adjacent second pins in the same row at the other end away from the display region.

9. The chip-on-film film according to claim 8, wherein the second pins in the same row are symmetrically distributed relative to a second reference line, and the second reference line is a perpendicular bisector of a boundary of the chip-on-film film along the first direction.

10. The chip-on-film film according to claim 9, wherein an included angle between each of the second pins and the second reference line gradually increases with increase of a distance between each of the second pins and the second reference line.

11. The chip-on-film film according to claim 9, wherein the included angle between each of the second pins and the second reference line is greater than or equal to about 78 degrees, and less than or equal to 84 degrees.

12. The chip-on-film film according to claim 8, wherein each of the second pins has same shape and size.

13. The chip-on-film film according to claim 12, wherein each of the second pins has a width greater than or equal to about 6 μm, and less than or equal to about 43 μm; and
each of second pins has a length greater than or equal to about 800 μm, and less than or equal to about 1300 μm.

14. The chip-on-film film according to claim 8, wherein a spacing of various of the second pins is greater than or equal to about 7 μm, and less than or equal to about 15 μm.

15. A display device, comprising
a display panel, wherein the display panel comprises:
a display region and a bonding region,
wherein the bonding region comprises: a first substrate and at least one row of first pins provided on a side of the first substrate, the first pins are provided along a first direction and are independent of each other, and
a distance between two adjacent first pins in a same row at one end near the display region is larger than a distance between the two adjacent first pins in the same row at the other end away from the display region, so that the at least one row of the first pins as a whole exhibit an inverted trapezoidal structure with a long side near the display region; and
a chip-on-film film, wherein the chip-on-film film is attached to the bonding region of the display panel, and the chip-on-film film comprises:
a second substrate and at least one row of second pins arranged on a side of the second substrate, wherein the second pins are arranged along a second direction and are independent of each other, and each of the second pins is configured to be bonded with a corresponding first pin, a distance between two adjacent second pins in a same row at one end near the display region is greater than a distance between the two adjacent second pins in the same row at the other end away from the display.

16. The display panel according to claim 3, wherein the included angle between each of the first pins and the first reference line is greater than or equal to about 78 degrees and less than or equal to 84 degrees.

17. The display panel according to claim 16, wherein each of the first pins has same shape and size.

18. The display panel according to claim 17, wherein each of the first pins has a width greater than or equal to about 11 μm, and less than or equal to about 47 μm; and
each of first pins has a length greater than or equal to about 600 μm, and less than or equal to about 1100 μm.

19. The display panel according to claim 18, wherein a spacing between various of the first pins is greater than or equal to about 3 μm, and less than or equal to about 10 μm.

20. The chip-on-film film according to claim 10, wherein the included angle between each of the second pins and the second reference line is greater than or equal to about 78 degrees, and less than or equal to 84 degrees.
